(19) United States
(12) Patent Application Publication
(10) Pub. No.: US 2024/0344199 A1
(43) Pub. Date: Oct. 17, 2024

(54) SEMICONDUCTOR PROCESSING CHAMBER LID AND COATING

(71) Applicant: Applied Materials, Inc., Santa Clara, CA (US)

(72) Inventors: Yogananda Sarode Vishwanath, Bengaluru (IN); Anand KUMAR, Bengaluru (IN); George KIM, Cupertino, CA (US)

(21) Appl. No.: 18/456,836

(22) Filed: Aug. 28, 2023

(30) Foreign Application Priority Data
Apr. 11, 2023 (IN) 202341026758

(51) Int. Cl. C23C 16/455; C23C 16/52; H01J 37/32; H01L 21/02

(52) U.S. Cl. CPC C23C 16/45563; C23C 16/52; H01J 37/32449; H01J 37/32798; H01L 21/02274; H01J 2237/3321; H01J 2237/334

(57) ABSTRACT

Semiconductor processing systems and system components are described. The system components include a chamber lid of a semiconductor processing chamber that includes a dielectric material having a substantially disk shape and integrating a lid portion and a gas delivery nozzle portion into a single structure. The chamber lid includes a plurality of gas flow paths that each traverse a region of the chamber lid from an input location at a first surface of the chamber lid to a respective output location on a different surface of the chamber lid and through which etch gases are distributed to particular portions of a processing region of the processing chamber.

### BACKGROUND

This specification relates to semiconductor systems, processes, and equipment.

Plasma etching can be used in semiconductor processing to fabricate integrated circuits. Integrated circuits can be formed from layer structures including multiple (e.g., two or more) layer compositions. Different etching gas chemistries, e.g., different mixtures of gases, can be used to form a plasma in the processing environment such that a given etching gas chemistry can have increased precision and higher selectivity for a layer composition to be etched. As scaling of integrated circuits continues to move towards smaller features and increased aspect ratios, there is a growing need for precision etching of layer structures.

### SUMMARY

This specification describes technologies for integrating a lid of a plasma-based processing chamber with a gas delivery nozzle to form a single composite structure. One type of plasma source is an inductively coupled plasma. In some plasma-based processing chambers, the plasma source is located above a lid of the chamber. During processing, an etching gas mixture flows through the gas delivery nozzle to form a plasma in a processing region of the chamber. Charged particles of the plasma are drawn towards an exposed surface of a substrate retained in the processing region of the chamber to perform an etching process on the exposed surface. Compositions of etching gas mixtures can be selected to etch different layer compositions, for example, a first etching gas mixture to etch silicon oxide (SiO) and a second etching gas mixture to etch silicon nitride (SiN). A semiconductor processing chamber can include one or more (e.g., two or more) processing regions, each with a respective substrate holder to retain a respective substrate and individually controllable etching gas mixtures to form a respective plasma in the processing regions.

In inductively coupled plasma base fabrication systems, the lid is composed of a dielectric material to provide a dielectric window allowing the transfer of energy into the chamber. A lid can be formed that integrates a portion of the processing chamber adjacent to the plasma source with a gas delivery nozzle that supplies one or more etching gas mixtures to the chamber. The integrated lid can be formed from a single dielectric material configured to provide both a vacuum seal for the top of the chamber as well as various gas paths for providing a particular distribution of etch gases to the processing chamber.

This specification further describes technologies for providing a coating to the integrated lid or other portions of the processing chamber. In particular, a nanostructured ceramic-matrix coating is described in which ceramic nanoparticles are combined with a polymer binder to form one or more layers. The coating can be used to help protect the integrated lid and chamber walls from the etch plasma. In addition to providing a coating, the nanostructured ceramic-matrix material can be used to repair an existing coating or substrate material, e.g., that has eroded or partially eroded, as well as to form new components in an additive manufacturing process that builds entire components from a composite mixture of ceramic nanoparticles and polymer.

In general, one innovative aspect of the subject matter described in this specification can be embodied in a system for semiconductor processing. The system includes a chamber body including multiple walls for enclosing a processing region, a first substrate support within the chamber body and configured to retain a substrate in the processing region of the chamber, and a plasma source configured to direct radio frequency (“RF”) energy into the chamber body. The system also includes a chamber lid configured to enclose the first processing region when in a closed position relative to the chamber body. The chamber lid integrates a lid portion and a gas delivery nozzle portion into a single structure, the chamber lid being formed from a dielectric material configured to allow RF energy generated by the plasma source to pass through the lid. The chamber lid includes multiple gas flow paths that each traverse a region of the chamber lid from an input location at a first surface of the chamber lid to a respective output location on a different surface of the chamber lid through which etch gases are distributed to particular portions of the processing region.

In general, another innovative aspect of the subject matter described in this specification can be embodied in a chamber lid of a semiconductor processing chamber. The chamber lid includes a dielectric material having a substantially disk shape and integrating a lid portion and a gas delivery nozzle portion into a single structure. The chamber lid further includes multiple gas flow paths that each traverse a region of the chamber lid from an input location at a first surface of the chamber lid to a respective output location on a different surface of the chamber lid and through which etch gases are distributed to particular portions of a processing region of the processing chamber.

In general, another innovative aspect of the subject matter described in this specification can be embodied in a structure embodied in a machine readable medium used in a design process. The structure includes a chamber lid including a dielectric material having a substantially disk shape and integrating a lid portion and a gas delivery nozzle portion into a single structure. The chamber lid includes multiple gas flow paths that each traverse a central region of the chamber lid from an input location at a first surface of the chamber lid to a respective output location on a different surface of the chamber lid.

In general, another innovative aspect of the subject matter described in this specification can be embodied in method of forming a coating on a structure. The method includes forming a first composite layer, the first composite layer including a ceramic nanoparticles and a polymer binder, wherein the polymer is cured to form the first layer. The method includes forming one or more second composite layers in sequential order on top of the first composite layer, each second composite layer including the ceramic nanoparticles and polymer that is cured after being formed on a preceding composite layer. The method includes forming a top layer, wherein the top layer has a surface substantially made of the ceramic nanoparticles.

Other embodiments of these aspects include corresponding systems, computer systems, apparatus, and computer programs recorded on one or more computer storage devices.

The subject matter described in this specification can be implemented in these and other embodiments so as to realize one or more of the following advantages. Inductively coupled plasma generates a large amount of heat. Forming a lid assembly that combines a lid and gas delivery nozzle of a same material reduces thermal mismatch between the gas delivery nozzle and the lid that can occur when formed from separate components made from separate materials. Additionally, forming the lid and gas delivery structures from a single piece of material allows for a better vacuum seal of the processing chamber. In particular, eliminating a gap between mechanically coupled gas delivery nozzle and lid components that exists when formed of two separate components reduces mechanical stress and potential gaps. The stresses or gaps in response to temperature and vacuum conditions could result in exposure of interior surfaces to plasma as well as reduction or loss of vacuum. A single lid can also reduce stresses in coupling the lid assembly to other components. In particular, etch gases are delivered to the gas delivery nozzle through a gas delivery hub that is attached to lid. Using an integrated lid and gas delivery nozzle allows for secure attachment without the use of clamping to a narrow portion of the lid between the clamps and the separate gas delivery nozzle component. Avoiding clamping to a narrow neck of lid structure reduces mechanical stress on the neck region of the lid and thereby reduces risk of cracking or other lid assembly damage.

Using nanoparticles combined with a polymer binder allow for forming a coating having multiple layers. The coating can be thicker and have fewer flaws than coatings formed through other techniques such as plasma spay. Increased thickness can increase a longevity of the component, e.g., increasing a length of time in which a plasma-based processing chamber can operate before needing repair or replacement of the coating. The nanoparticle and polymer composite can be disposed on a surface using techniques that are less complex and costly than conventional processes such as plasma spray. Eroded nanoparticles from the coating are less likely to impact a substrate/wafer being processed in a plasma-based processing chamber because of their small size. Instead they are more likely to be exhausted from the processing chamber by operating vacuum pumps. Coatings can be repaired by applying a new layer to some or all of a surface allowing for longer overall lifespan of the coating.

Premixing of nanoparticles with the polymer binder and extrusion forming (without the need for thermal energy) near-net shape parts can be faster and cheaper than production of large ceramic components, which is often complex and expensive. Using the extrusion forming of plasma-resistant components or surface allows for component formation without physical and chemical challenges associated with high temperature processing involved in conventional techniques, particularly when using and retaining nanoparticles.

Although the remaining disclosure will identify specific etching processes using the disclosed technology, it will be readily understood that the systems and methods are equally applicable to a variety of other processes as can occur in the described chambers. Accordingly, the technology should not be considered to be so limited as for use with the described etching processes alone. The disclosure will discuss one possible system and chamber that can be used with the present technology before describing systems and methods or operations of exemplary process sequences according to some embodiments of the present technology. It is to be understood that the technology is not limited to the equipment described, and processes discussed can be performed in any number of processing chambers and systems.

### BRIEF DESCRIPTION OF THE DRAWINGS

FIG. 1 shows a schematic cross-sectional view of an example processing chamber.

FIG. 2A shows a schematic cross-sectional partial view of an example plasma processing chamber.

FIG. 2B shows a schematic cross-section of a threaded portion of a lid of the plasma processing chamber of FIG. 2A.

FIG. 3A shows a schematic cross-sectional view of an example lid of a plasma processing chamber.

FIG. 3B shows a top view of the example lid of FIG. 3A.

FIG. 4 shows a first schematic cross-sectional view of the gas delivery nozzle illustrating first gas paths through the lid of FIG. 3A.

FIG. 5 shows a second schematic cross-sectional view of the gas delivery nozzle illustrating second gas paths through the lid of FIG. 3A.

FIG. 6A shows a schematic cross-sectional view of an example lid of a plasma processing chamber.

FIG. 6B shows a top view of the example lid of FIG. 6A.

FIG. 7 shows a first schematic cross-sectional view of a gas delivery nozzle illustrating a first gas path through the lid of FIG. 6A.

FIG. 8 shows a second schematic cross-sectional view of the gas delivery nozzle illustrating a second gas path through the lid of FIG. 6A.

FIG. 9A shows a schematic cross-sectional view of an example lid of a plasma processing chamber.

FIG. 9B shows a top view of the example lid of FIG. 9A.

FIG. 10 shows a first schematic cross-sectional view of a gas delivery nozzle illustrating a first gas path through the lid of FIG. 9A.

FIG. 11 shows a second schematic cross-sectional view of the gas delivery nozzle illustrating a second gas path through the lid of FIG. 9A.

FIG. 12A shows a top view of an example lid of a plasma processing chamber.

FIG. 12B shows a schematic cross-sectional view of the lid of FIG. 12A.

FIG. 13A shows a top view of an example lid of a plasma processing chamber.

FIG. 13B shows a schematic cross-sectional view of the lid of FIG. 13A.

FIGS. 14A-C show cross sectional views of an example of building layers on a base material.

FIG. 15 is a flow diagram of an example method of forming a nanostructured ceramic-matrix coating.

FIG. 16 is a flow diagram of an example method of additively manufacturing a structure from a nanomaterial.

FIG. 17 is a block diagram of an example generic computing system.

Like reference numbers and designations in the various drawings indicate like elements.

### DETAILED DESCRIPTION

The present specification describes technologies for integrating a lid of a plasma-based processing chamber with a gas delivery nozzle to form a single composite structure. The lid can be formed from a single dielectric material that includes structures for delivering etch gasses to the processing chamber. Gas distribution pathways are formed in the lid to direct gases to different regions of the processing chamber to facilitate etch processes on different regions of a substrate. Different shapes of gas distribution pathways as well as different shapes of a gas delivery nozzle portion of the lid can be used to create different distributions of etch gases into the processing chamber.

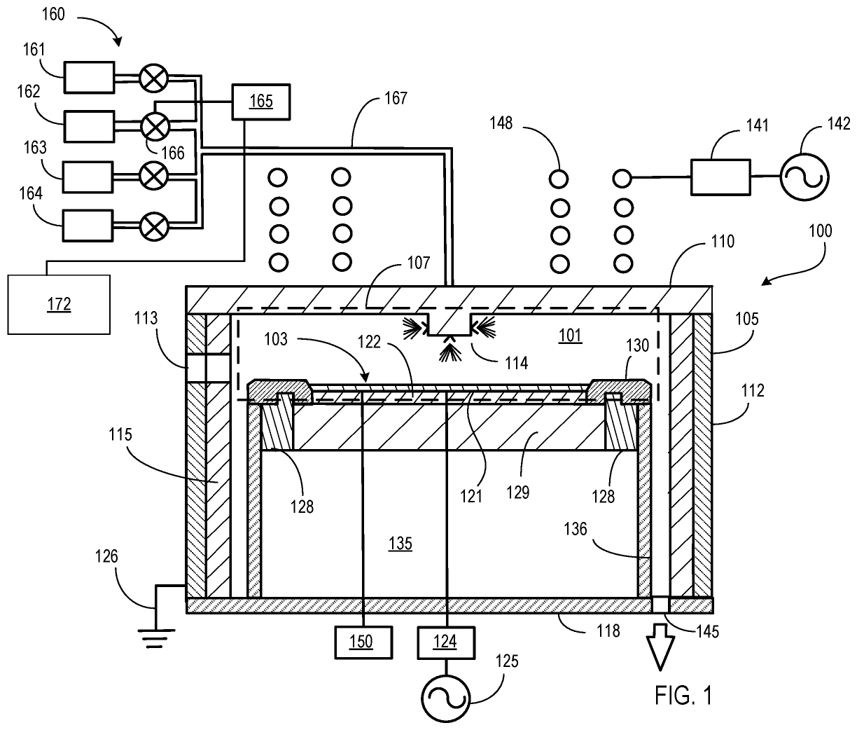

FIG. 1 illustrates a schematic cross-sectional view of an example processing chamber 100 suitable for etching one or more material layer(s) disposed on a substrate 103 (e.g., also referred to as a “wafer”) in the processing chamber 100, e.g., a plasma processing chamber. The processing chamber 100 includes a chamber body 105 defining a chamber volume 101 in which a substrate can be processed. The chamber body 105 has sidewalls 112 and a bottom 118 which are coupled with ground 126. The sidewalls 112 can include a liner 115 to protect the sidewalls 112 and extend the time between maintenance cycles of the plasma processing chamber 100. The chamber body 105 is supportive of a chamber lid 110 to enclose the chamber volume 101. The chamber body 105 can be fabricated from, for example, aluminum or other suitable materials. A substrate access port 113 is formed through the sidewall 112 of the chamber body 105, which can facilitate the transfer of the substrate 103 into and out of the plasma processing chamber 100. Access port 113 can be coupled with a transfer chamber and/or other chambers (not shown) of a substrate processing system, e.g., to perform other processes on the substrate. A pumping port 145 is formed through the bottom 118 of the chamber body 105 and connected to the chamber volume 101. A pumping device can be coupled through the pumping port 145 to the chamber volume 101 to evacuate and control the pressure within the processing volume. The pumping device can include one or more pumps and throttle valves.

Chamber volume 101 includes a processing region 107, e.g., a station for processing a substrate. A substrate support 135 can be disposed in the processing region 107 of chamber volume 101 to support the substrate 103 during processing. The substrate support 135 can include an electrostatic chuck 122 for holding the substrate 103 during processing. The electrostatic chuck (“ESC”) 122 can use the electrostatic attraction to hold the substrate 103 to the substrate support 135. The ESC 122 can be powered by a radio frequency (“RF”) power supply 125 integrated with a match circuit 124. The ESC 122 can include an electrode 121 embedded within a dielectric body. The electrode 121 can be coupled with the RF power supply 125 and can provide a bias which attracts plasma ions, formed from the process gases in the chamber volume 101, to the ESC 122 and substrate 103 seated on the pedestal. The RF power supply 125 can cycle on and off, or pulse, during processing of the substrate 103. The ESC 122 can have an isolator 128 for the purpose of making the sidewall of the ESC 122 less attractive to the plasma to prolong the maintenance life cycle of the ESC 122. Additionally, the substrate support 135 can have a cathode liner 136 to protect the sidewalls of the substrate support 135 from the plasma gases and to extend the time between maintenance of the plasma processing chamber 100.

Electrode 121 can be coupled with a DC power source 150. The power source 150 can provide a chucking voltage of about 200 volts to about 2000 volts to the electrode 121. The power source 150 can also include a system controller for controlling the operation of the electrode 121 by directing a DC current to the electrode 121 for chucking and de-chucking the substrate 103. The ESC 122 can include heaters disposed within the ESC 122 and connected to a power source for heating the substrate, while a cooling base 129 supporting the ESC 122 can include conduits for circulating a heat transfer fluid to maintain a temperature of the ESC 122 and substrate 103 disposed thereon. The ESC 122 can be configured to perform in the temperature range required by the thermal budget of the device being fabricated on the substrate 103. For example, the ESC 122 can be configured to maintain the substrate 103 at a temperature of about −150° C. or lower to about 500° C. or higher depending on the process being performed. A cover ring 130 can be disposed on the ESC 122 and along the periphery of the substrate support 135. The cover ring 130 can be configured to confine etching gases to a desired portion of the exposed top surface of the substrate 103, while shielding the top surface of the substrate support 135 from the plasma environment inside the plasma processing chamber 100.

A gas panel 160 (e.g., also referred to herein as “gas distribution manifold”) can be coupled by a gas line 167 with the chamber body 105 through chamber lid 110 to supply process gases into the chamber volume 101. The gas panel 160 can include one or more process gas sources 161, 162, 163, 164 and can additionally include inert gases, non-reactive gases, and reactive gases, as can be used for any number of suitable processes. Examples of process gases that can be provided by the gas panel 160 include, but are not limited to, hydrocarbon containing gases including methane, sulfur hexafluoride, silicon chloride, silicon tetrachloride, carbon tetrafluoride, hydrogen bromide. Process gases that can be provided by the gas panel can include, but are limited to, argon gas, chlorine gas, nitrogen, helium, or oxygen gas, sulfur dioxide, as well as any number of additional materials. Additionally, process gasses can include nitrogen, chlorine, fluorine, oxygen, or hydrogen containing gases including, for example, BCl₃, C₂F₄, C₄F₈, C₄F₆, CHF₃, CH₂F₂, CH₃F, NF₃, NH₃, CO₂, SO₂, CO, N₂, NO₂, N₂O, and H₂, among any number of additional suitable precursors. Process gases from process gas sources, e.g., sources 161, 162, 163, 164, can be combined to form one or more etching gas mixtures. For example, gas panel 160 includes one or more process gas sources specific to oxide-based etching chemistries. In another example, gas panel 160 includes one or more process gas sources specific to nitride-based etching chemistries.

Gas panel 160 includes various valves, pressure regulators (not shown), and mass flow controllers (not shown) arranged with respect to the gas sources 161, 162, 163, 164 to control the flow of the process gases from the sources. Valves 166 can control the flow of the process gases from the sources 161, 162, 163, 164 from the gas panel 160. Operations of the valves, pressure regulators, and/or mass flow controllers can be controlled by a controller 165. Controller 165 can be operably coupled to an electro-valve (EV) manifold (not shown) to control actuation of one or more of the valves, pressure regulators, and/or mass flow controllers. The lid 110 can incorporate a gas delivery nozzle 114. The gas delivery nozzle 114 can include one or more openings for introducing the process gases from the sources 161, 162, 163, 164 of the gas panel 160 into the chamber volume 101. After the process gases are introduced into the plasma processing chamber 100, the gases can be energized to form a plasma. An antenna 148, such as one or more inductor coils, can be provided adjacent to the plasma processing chamber 100. An antenna power supply 142 can power the antenna 148 through a match circuit 141 to inductively couple energy, such as RF energy, to the process gas to maintain a plasma formed from the process gas in the chamber volume 101 of the plasma processing chamber 100. The operation of the power supply 142 can be controlled by a controller, such as controller 165, that also controls the operation of other components in the plasma processing chamber 100.

The controller 165 can be used to control the process sequence, regulating the gas flows from the gas panel 160 into the plasma processing chamber 100, and other process parameters. Software routines, when executed by a computing device having one or more processors (e.g., a central processing unit (CPU)) in data communication with one or more memory storage devices, transform the computing device into a specific purpose computer such as a controller, which can control the plasma processing chamber 100 such that the processes are performed in accordance with the present disclosure. The software routines can also be stored and/or executed by one or more other controller(s) that can be associated with the plasma processing chamber 100.

In some embodiments, controller 165 is in data communication with a characterization device 172. Characterization device 172 can include one or more sensors (e.g., image sensors) operable to collect processing data related to processing chamber 100. For example, characterization device 172 includes an optical emission spectroscopy device configured to monitor a signal, e.g., emitted light of a plasma, within a processing region of the processing chamber 100. For example, a signal can be a primary or highest intensity wavelength of emitted light. Characteristics of the emitted light (e.g., wavelength and intensity) from the plasma within the processing region can depend in part on an etching gas mixture used to generate the plasma as well as a layer composition of the layer being etched. For example, each etching gas mixture and corresponding layer composition being etched can have a respective signal signature. Emitted wavelengths that are unique or distinguishing for each etching gas mixture and corresponding layer composition can be monitored to determine an etching condition of the layer being etched. For example, a thickness remaining of the layer being etched. Characteristics of the emitted light from the plasma can change, e.g., based on the etching process. For example, an intensity of a monitored signal can change as material is removed from the layer being processed. Characterization device 172 can be configured to collect processing data including the respective signals corresponding to the etching gas mixtures utilized in the wafer processing and corresponding layer compositions of the structure being processed in the processing chamber 100. Controller 165 can receive processing data from the characterization device 172 and determine, from the processing data, one or more actions to perform.

In some embodiments, at a termination point of etching process(es) for the wafer, an automatic or semi-automatic robotic manipulator (not shown) can be utilized to transfer the wafer(s) from the substrate support out of the process chamber, e.g., through substrate access port 113. For example, the robotic manipulator can transfer the wafer to another chamber (or another location) to perform another step in a fabrication process.

Although described with respect to FIG. 1 as a process chamber including a substrate support disposed within a processing region of the chamber volume, two or more substrate supports can be disposed within the same chamber volume in respective processing regions, e.g., in respective processing stations. For example, a processing chamber 100 can be a tandem processing chamber including two processing regions each with respective substrate supports configured to retain respective wafers during etching process(es). The processing chamber 100 can include two or more processing regions within the chamber volume 101 to facilitate parallel processing of two or more substrates in respective processing regions. The processing regions can be substantially isolated such that an etching process in a first processing region has minimal effect on an etching process in a second processing region and vice-versa.

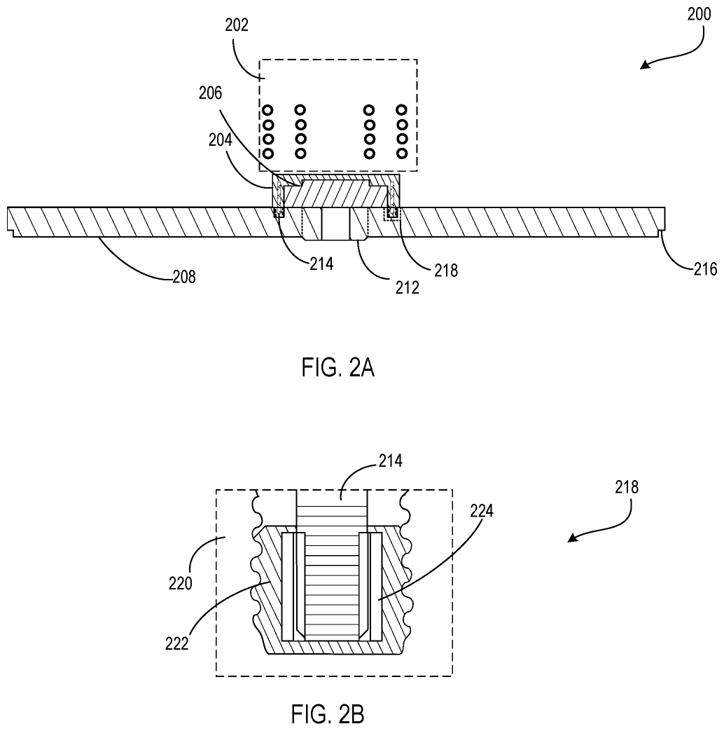

FIG. 2A shows a schematic cross-sectional partial view 200 of an example plasma processing chamber. The partial view 200 includes an inductively coupled plasma (“ICP”) source 202, a mounting structure 204, a gas hub 206, and a lid 208. The lid 208 incorporates a gas delivery nozzle 212 within a central region of the lid 208.

The ICP source 202 includes one or more inductor coils coupled to a power supply configured to power the one or more inductor coils. The inductor coils inductively couple energy, such as RF energy, through the gas hub 206 and lid 208 to maintain a plasma formed from the etch gases distributed within a plasma processing chamber. The ICP source 202 is oriented so that the inductively coupled energy causes charged particles of the etch gas plasma to flow toward a substrate held in the plasma processing chamber.

The mounting structure 204 can be used to mount and align the gas hub 206 to the lid 208. The gas hub receives etch gases from one or more gas lines each providing one or more process gases from the gas panel. The gas hub 206 can have one or more plenums formed within to separate etch gases to be provided to different gas flow paths of the gas delivery nozzle 212.

Because the lid 208 integrates the gas delivery nozzle 212, the mounting structure 204 can be attached more securely and with less mechanical stress than clamping to a lid having a separate gas delivery nozzle. In the example shown in FIG. 2A, one way to attach the mounting structure 204 and lid 208 includes forming a group of mounting holes into the lid 208. The depth of the holes is less than the thickness of the lid 208. In particular, the holes can be configured to accept a threaded insert made from a plastic material that can then receive a fastener such as a bolt or other threaded attaching structure 216 from the mounting structure 204. Although four mounting holes are shown in FIG. 2A, the number of mounting holes may depend on the particular structural requirements. For example, 3, 6, 8, or more mounting holes can be used.

FIG. 2B shows an enlarged view of the cross-section of a threaded portion 218 of the lid 208 of the plasma processing chamber of FIG. 2A. In the example illustrated in FIG. 2B, a threaded mounting hole 220 is formed in the lid 208. A threaded insert 222 can then be positioned within the threaded mounting hole. In particular, the threaded insert can include an embedded helical coil 224. The helical coil can be a metal coil that can receive the threaded attaching structure 216 and provide a stronger attachment with less risk of damage than threading the attaching structure 214 directly into the ceramic lid material. In particular, the attaching structure can be removed and reattached frequently and securely.

The threaded insert 222 is formed from an insulating or dielectric material to avoid interference with the inductive energy. For example, the insert can be made from Polyamidimide such as Torlon® having a high strength and heat resistance. The helical coil 224 can be a metallic helical coil such as a Heli-Coil®. The attaching structure 216 can be metallic or plastic material. A plastic material may be chosen, for example, to reduce the amount of conductive material in the magnetic field induced by the plasma source.

The lid 208 is formed from a single piece of dielectric material. For example, the lid 208 can be formed from Alumina (aluminum oxide Al₂O₃), quartz, or other suitable ceramic materials such as Yttria (Yttria oxide Y₂0₃). The lid 208 can be shaped to form a vacuum seal with sidewalls of the plasma processing chamber during operation. For example, the lid 208 can be substantially disk shaped conforming to an end face of a cylindrical processing region of the plasma processing chamber. The lid 208 can include a lip edge 216 configured to seat the lid 208 on one or more sidewall edges of the plasma processing chamber.

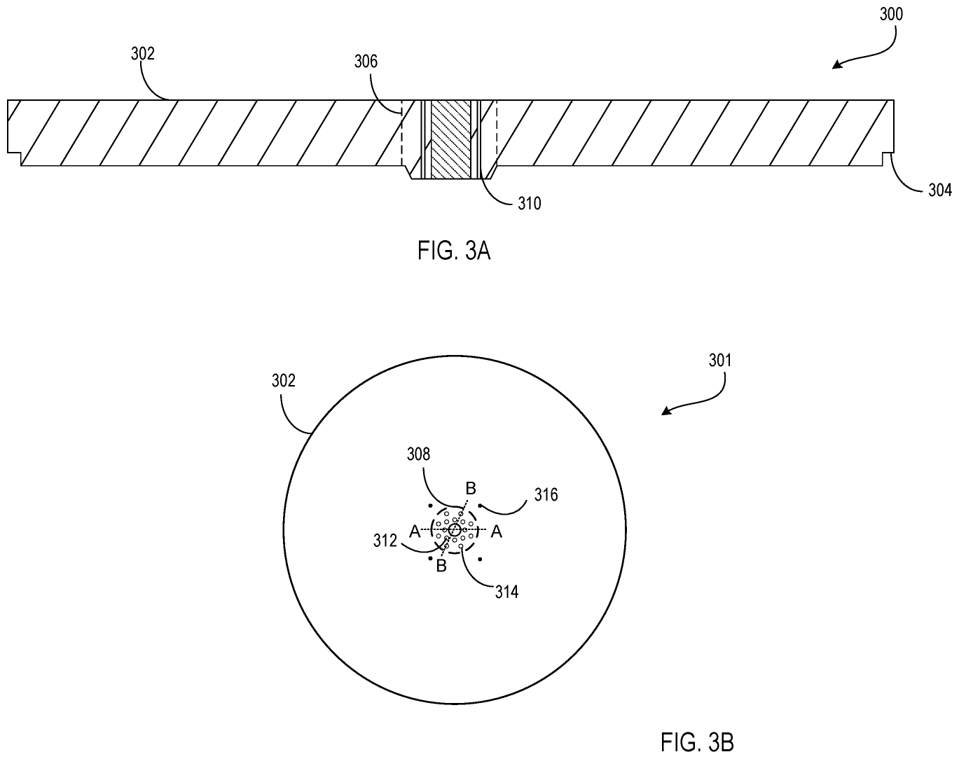

The lid 208 incorporates the gas delivery nozzle 212. The gas delivery nozzle 212 is formed from the same piece of dielectric material, but is conceptually represented by dashed lines 212 roughly corresponding to a diameter of a separate nozzle component and positioned within a central region of the lid 208. The gas delivery nozzle 212 portion of the lid 208 includes a number of gas paths configured to deliver process gases from one or more plenums of the gas hub 206 through the lid 208 and into the chamber volume. The gas paths are described in more detail with respect to FIGS. 3-11 below. In some implementations, the lid 208 includes an aperture substantially in the center of the gas delivery nozzle that can be used to contain sensors or other diagnostic components for obtaining information from within the plasma processing chamber.

In some implementations, the lid 208 is coated with a material on a surface facing the plasma processing chamber. The plasma facing surface is exposed to the plasma generated during plasma processing. To protect the lid 208, the surface may be coated with another material, for example, Yttria.

FIG. 3A shows a schematic cross-sectional view 300 of an example lid 302 of a plasma processing chamber. FIG. 3B shows a top view 301 of the example lid 302 of FIG. 3A. The lid 302 is formed from a single piece of dielectric material, e.g., a ceramic material such as Alumina or Yttria, quartz, or other suitable dielectric material. The lid 302 can be substantially disk shaped. As illustrated by top view 301, the lid 302 can have a substantially circular top surface having a particular diameter. In this specification, a “top” of the lid refers to a side of the lid facing the gas hub. The shape and diameter can be configured according to the particular plasma processing chamber design.

The lid 302 has a specified thickness that can be determined based on various design parameters including material, strength needed, and overall system design. For example, the plasma processing chamber can operate in a vacuum and under high heat resulting from the plasma formation. The lid thickness may be partially based on the structural needs to satisfy operational parameters of maintaining a vacuum seal and avoiding heat or expansion damage. The lid 302 can include a lip portion 304 for seating the lid on one or more sidewall edges on the opening of the plasma processing chamber.

For clarity of discussion, a portion of the lid 302 forming a gas delivery nozzle is demarcated by dashed lines 306 in the cross-sectional view 300 and dashed line 308 in the top view 301. Although highlighted by dashed lines, the structures forming the gas delivery nozzle are formed from the lid itself and not a separate component from the lid 302. In the example lid 302, a portion of the lid 302 around the gas delivery nozzle 306 protrudes out from the surface of the lid 302 on the plasma chamber facing side of the lid.

A pair of gas paths 310 passing through the lid 302, are shown in the cross-sectional view 300. These are an example pair of multiple gas paths. In particular, as shown in top view 301, an inner set of gas path holes 312 substantially form a ring of holes a particular radial distance from a center of the lid 302. The inner set of gas path holes 312 can direct etch gasses from one or more plenums of a gas hub and through the body of the gas delivery nozzle 306. For example, the inner set of gas path holes 312 can be positioned to direct charged particles formed from the etch gases in the process chamber to a particular central region of a target substrate.

An outer set of gas path holes 314 substantially form a ring of holes a particular radial distance from the center of the lid 302 that is greater than the radial distance of the inner set of gas path holes 312. The outer set of gas path holes 314 can direct etch gasses from one or more plenums of the gas hub and through the body of the gas delivery nozzle 3064. For example, the outer set of gas path holes 314 can be positioned to direct charged particles formed from the etch gases in the process chamber to a particular edge region of a target substrate.

The number of gas paths represented by the set of inner gas path holes and the set of outer gas path holes can vary depending on the particular application and design of the plasma processing chamber. Moreover, the arrangement need not align with concentric inner and outer circles, but can have varied locations or different patterns. For example, in some implementations, multiple sets of gas paths can correspond to multiple etching regions of a substrate and not just inner and edge regions, e.g., three sets of gas paths corresponding to inner, middle, and edge etch regions of the substrate.

The top view 301 also illustrates four mounting holes 316. The mounting holes 316 can be similar to the mounting holes described above with respect to FIG. 2 and used to secure components of an inductively coupled plasma source and the gas hub to the lid 302.

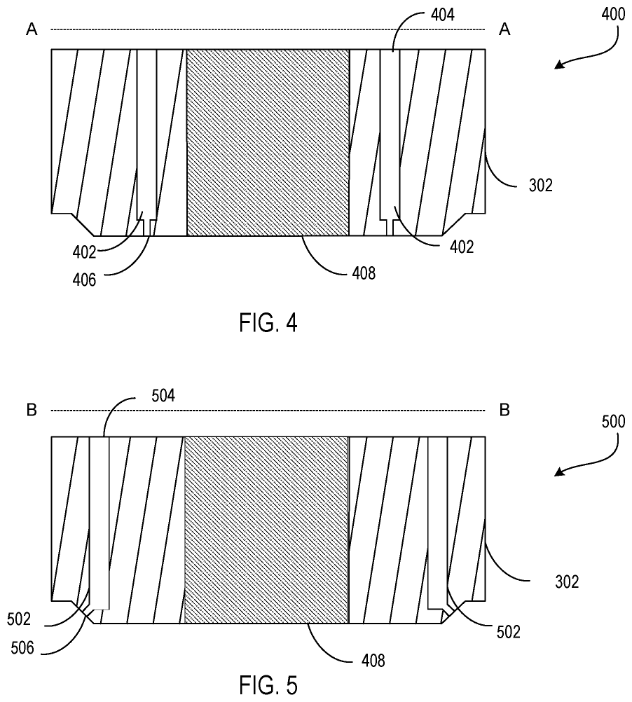

FIG. 4 shows a first schematic cross-sectional view 400 of the gas delivery nozzle 306 illustrating first gas paths 402 through the lid 302 of FIG. 3A. In particular, cross-sectional view 400 corresponds to a cross section along the path A-A shown in FIG. 3B.

As shown in FIG. 4, the lid 302 includes a pair of gas paths 402. Specifically, these gas paths correspond to a pair of the inner set of gas path holes 312 shown in in FIG. 3B. Thus, there are multiple additional gas paths on different cross sections of the lid 302. In particular, etch gasses from the hub (e.g., hub 206 of FIG. 2) enter each respective gas path 402 at a corresponding input 404 and exit the gas delivery nozzle toward the process chamber through an output 406. Each gas path 402 can be, for example, a cylindrically formed hole through the lid 302. In the example shown in FIG. 4, the gas paths 402 narrow near the output 406. In other implementations, the diameter of the gas path is constant. Each gas path 402 corresponding to an inner set of gas paths can have outputs configured to direct charged particles formed from the etch gasses toward a central region of a substrate positioned in the process chamber.

A central portion 408 corresponds to an aperture formed through the center of the lid 302. The aperture can be a cylindrical opening in the lid that facilitates insertion of diagnostic, sensor, or other devices into the process chamber, for example, mounted for obtaining measurements during operation in vacuum or during offline maintenance. In some implementations, the cylindrical aperture can have different diameters or can be omitted entirely from the lid.

FIG. 5 shows a second schematic cross-sectional view 500 of the gas delivery nozzle 306 illustrating second gas paths 502 through the lid of FIG. 3A. In particular, cross-sectional view 400 corresponds to a cross section along the path B-B shown in FIG. 3B.

As shown in FIG. 5, the lid 302 includes a pair of gas paths 502. Specifically, these gas paths correspond to a pair of the outer set of gas path holes 314 shown in in FIG. 3B. Thus, there are multiple additional gas paths on different cross sections of the lid 302. In particular, etch gasses from the hub (e.g., hub 206 of FIG. 2) enter each respective gas path 502 at a corresponding input 504 and exit the gas delivery nozzle toward the process chamber through an output 506. Each gas path 502 can be, for example, a cylindrically formed hole through the lid 302. In the example shown in FIG. 4, the gas paths 502 narrow near the outputs 506. In other implementations, the diameter of the gas paths is constant. Each gas path 502 corresponding to an outer set of gas paths can have outputs configured to direct charged particles formed from the etch gasses toward a central region of a substrate positioned in the process chamber.

In particular, the gas paths 502 exit at an angle as compared to the gas paths 402 of FIG. 4. The angled output is facilitated by a portion of the lid 302 having a greater thickness than other portions of the lid 302. As shown in FIGS. 4 and 5, a protrusion 410 around the gas delivery nozzle projects a portion of the lid 302 into the process chamber when closed. The protrusion 410 can have a sloped edge that joins a surface of the protrusion with another surface of the lid 302. The outputs 506 of the gas paths 502 exit perpendicular to the sloped edge to direct the etch gases to a position corresponding, for example, to an edge region of the substrate.

Different etch gas mixtures can be passed through the gas paths 402 and gas paths 502, which can be independently controlled. As described above with respect to FIG. 1, the particular process gases used to form a particular etch gas mixture can depend on the etch operation being performed. The gas pressure applied to gasses passing through the gas paths 402 and gas paths 502 can also be independently controlled, for example, a part of controlling an etch rate to different portions of the substrate.

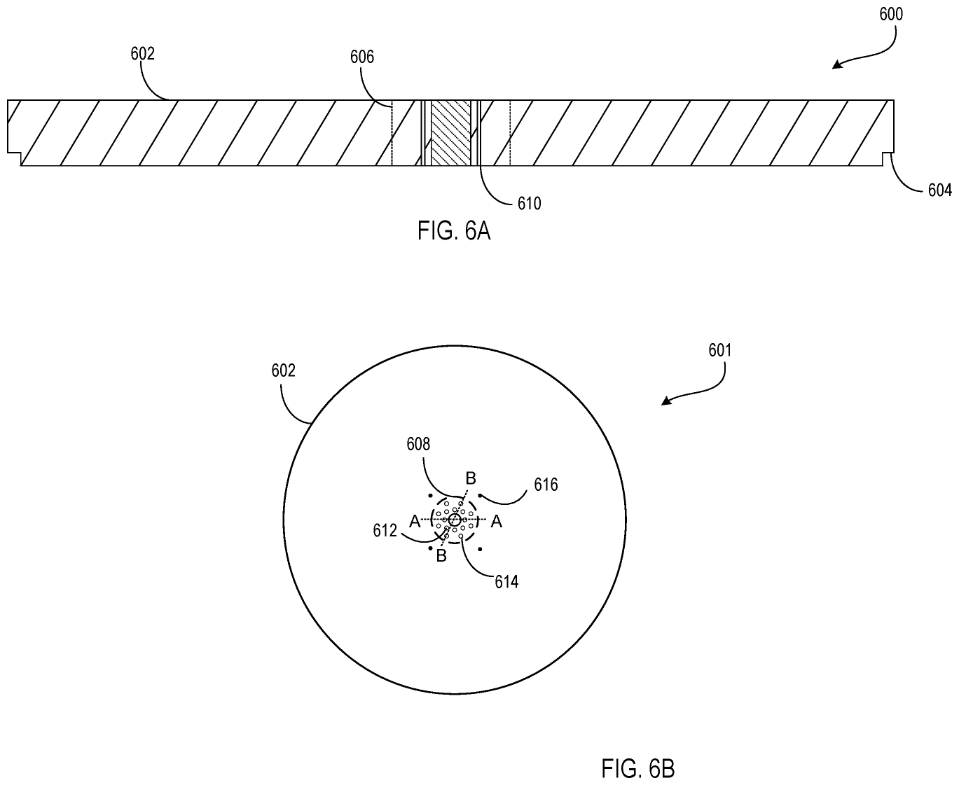

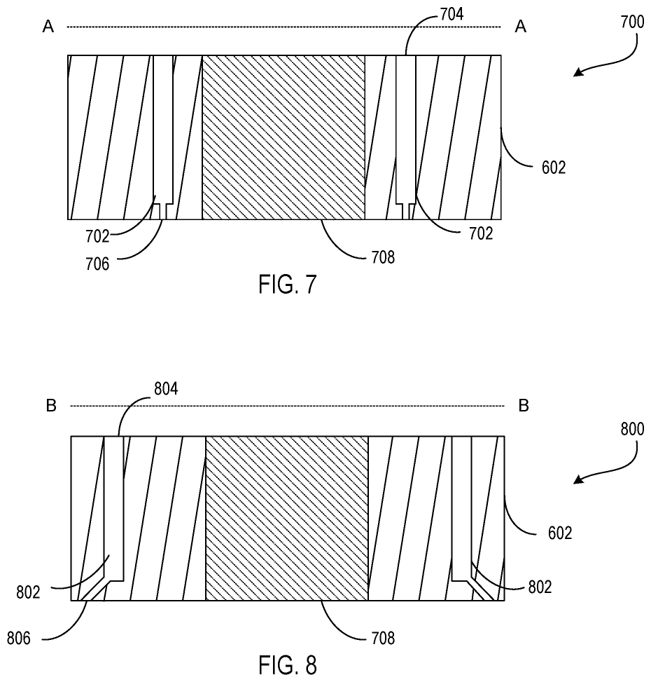

FIG. 6A shows a schematic cross-sectional view 600 of an example lid 602 of a plasma processing chamber. FIG. 6B shows a top view 601 of the example lid 602 of FIG. 6A.

The lid 602 is formed from a single piece of dielectric material, e.g., a ceramic material such as Alumina or Yttria, quartz, or other suitable dielectric material. The lid 602 can be substantially disk shaped. As illustrated by top view 601, the lid 602 can have a substantially circular top surface having a particular diameter. The shape and diameter can be configured according to the particular plasma processing chamber design.

The lid 602 has a specified thickness that can be determined based on various design parameters including material, strength needed, and overall system design. For example, the plasma processing chamber can operate in a vacuum and under high heat resulting from the plasma formation. The lid thickness may be partially based on the structural needs to satisfy operational parameters of maintaining a vacuum seal and avoiding heat or expansion damage. The lid 602 can include a lip portion 604 for seating the lid on one or more sidewall edges on the opening of the plasma processing chamber.

For clarity of discussion, a portion of the lid 602 forming a gas delivery nozzle is demarcated by dashed lines 606 in the cross-sectional view 600 and dashed line 608 in the top view 601. Although highlighted by dashed lines, the structures forming the gas delivery nozzle are formed from the lid itself and not a separate component from the lid 602. In the example lid 602, the portion of the lid 602 forming the gas delivery nozzle 606 is coplanar with other surfaces of the lid 602, in contrast to the protrusion shown in FIG. 3.

A pair of gas paths 610 passing through the lid 602, are shown in the cross-sectional view 600. These represent an example pair of multiple gas paths. In particular, as shown in top view 601, an inner set of gas path holes 612 substantially form a ring of holes a particular radial distance from a center of the lid 602. The inner set of gas path holes 612 can direct etch gasses from one or more plenums of a gas hub and through the body of the gas delivery nozzle 606. For example, the inner set of gas path holes 612 can be positioned to direct charged particles formed from the etch gases in the process chamber to a particular central region of a target substrate.

An outer set of gas path holes 614 substantially form a ring of holes a particular radial distance from the center of the lid 602 that is greater than the radial distance of the inner set of gas path holes 612. The outer set of gas path holes 614 can direct etch gasses from one or more plenums of the gas hub and through the body of the gas delivery nozzle 606. For example, the outer set of gas path holes 614 can be positioned to direct charged particles formed from the etch gases in the process chamber to a particular edge region of a target substrate.

The number and arrangement of gas paths represented by the set of inner gas path holes and the set of outer gas path holes can vary as described above with respect to FIG. 3B.

The top view 601 also illustrates four mounting holes 616. The mounting holes 616 can be similar to the mounting holes described above with respect to FIG. 2 and used to secure components of an inductively coupled plasma source and the gas hub to the lid 602.

FIG. 7 shows a first schematic cross-sectional view 700 of the gas delivery nozzle 606 illustrating first gas paths 702 through the lid 602 of FIG. 6A. In particular, cross-sectional view 700 corresponds to a cross section along the path A-A shown in FIG. 6B.

As shown in FIG. 7, the lid 602 includes a pair of gas paths 702. Specifically, these gas paths correspond to a pair of the inner set of gas path holes 612 shown in in FIG. 6B. Thus, there are multiple additional gas paths on different cross sections of the lid 602. In particular, etch gasses from the hub (e.g., hub 206 of FIG. 2) enter each respective gas path 702 at a corresponding input 704 and exit the gas delivery nozzle toward the process chamber through an output 706. Each gas path 702 can be, for example, a cylindrically formed hole through the lid 602. In the example shown in FIG. 7, the gas paths 702 narrow near the output 706. In other implementations, the diameter of the gas path is constant. Each gas path 702 corresponding to an inner set of gas paths can have outputs configured to direct charged particles formed from the etch gasses toward a central region of a substrate positioned in the process chamber.

A central portion 708 corresponds to an aperture formed through the center of the lid 602 and can be configured, or omitted, similarly to the aperture 408 described above with respect to FIG. 4.

FIG. 8 shows a second schematic cross-sectional view 800 of the gas delivery nozzle 606 illustrating second gas paths 802 through the lid of FIG. 6A. In particular, cross-sectional view 800 corresponds to a cross section along the path B-B shown in FIG. 6B.

As shown in FIG. 8, the lid 602 includes a pair of gas paths 802. Specifically, these gas paths correspond to a pair of the outer set of gas path holes 614 shown in in FIG. 6B. Thus, there are multiple additional gas paths on different cross sections of the lid 602. In particular, etch gasses from the hub (e.g., hub 206 of FIG. 2) enter each respective gas path 802 at a corresponding input 804 and exit the gas delivery nozzle toward the process chamber through an output 806. Each gas path 802 can be, for example, a cylindrically drilled hole through the lid 602. In the example shown in FIG. 8, the gas paths 802 narrow near the outputs 806. In other implementations, the diameter of the gas paths is constant. Each gas path 802 corresponding to an outer set of gas paths can have outputs configured to direct charged particles formed from the etch gasses toward an edge region of a substrate positioned in the process chamber.

In particular, the gas paths 802 exit at an angle as compared to the gas paths 702 of FIG. 7. The angle is formed by a bend in the gas path 802 within the body of the lid 602. Having an angle increases the distance between inner gas paths and outer gas paths without, for example, modifying the gas delivery mechanism of the gas hub to the top inputs of the gas paths. In particular, the angle and distance allows etch gases output from gas paths 802 to be directed to a position corresponding, for example, to an edge region of the substrate.

Different etch gas mixtures and etch gas pressures can be passed through the gas paths 702 and gas paths 802, which can be independently controlled, as described above with respect to FIGS. 4-5.

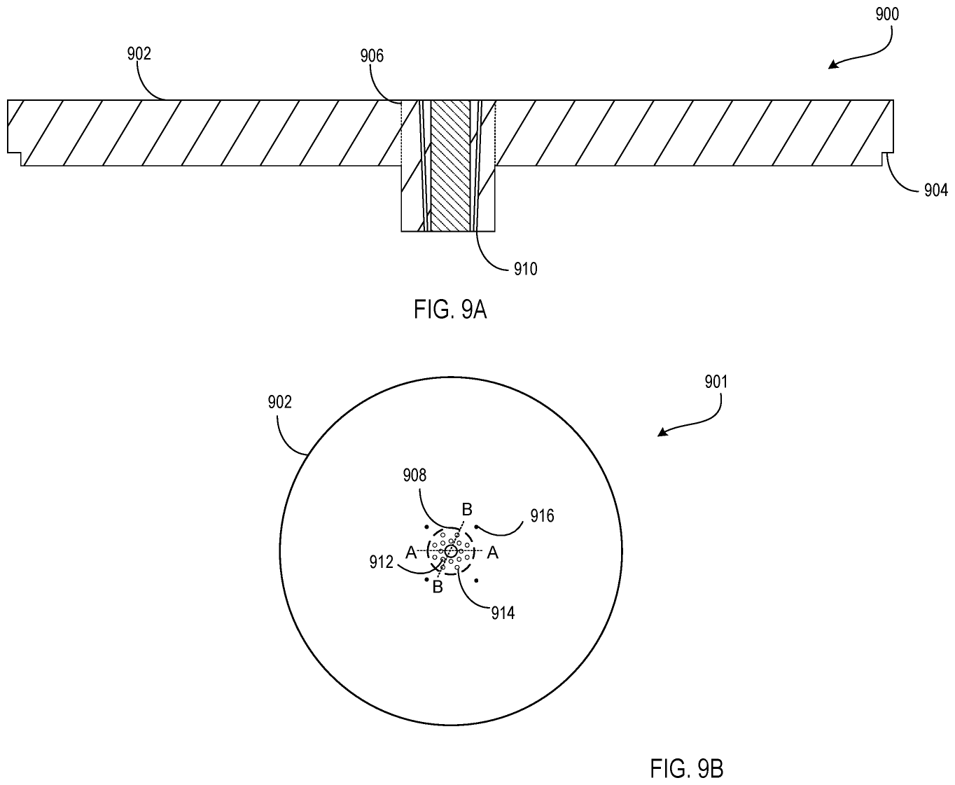

FIG. 9A shows a schematic cross-sectional view 900 of an example lid 902 of a plasma processing chamber. FIG. 9B shows a top view 901 of the example lid 902 of FIG. 9A. The lid 902 is formed from a single piece of dielectric material, e.g., a ceramic material such as Alumina or Yttria, quartz, or other suitable dielectric material. The lid 902 can be substantially disk shaped. As illustrated by top view 901, the lid 902 can have a substantially circular top surface having a particular diameter. The shape and diameter can be configured according to the particular plasma processing chamber design.

The lid 902 has a specified thickness that can be determined based on various design parameters including material, strength needed, and overall system design. For example, the plasma processing chamber can operate in a vacuum and under high heat resulting from the plasma formation. The lid thickness may be partially based on the structural needs to satisfy operational parameters of maintaining a vacuum seal and avoiding heat or expansion damage. The lid 902 can include a lip portion 904 for seating the lid on one or more sidewall edges on the opening of the plasma processing chamber.

For clarity of discussion, a portion of the lid 902 forming a gas delivery nozzle is demarcated by dashed lines 906 in the cross-sectional view 900 and dashed line 908 in the top view 901. Although highlighted by dashed lines, the structures forming the gas delivery nozzle are formed from the lid itself and not a separate component from the lid 902. In the example lid 902, a portion of the lid 902 around the gas delivery nozzle 906 protrudes out from the surface of the lid 902 on the plasma chamber facing side of the lid. In particular, in the example lid 902, the portion corresponding to the gas delivery nozzle 906 can include a cylindrical protrusion from the surface of the lid 902.

A pair of gas paths 910 passing through the lid 902, are shown in the cross-sectional view 900. These are an example pair of multiple gas paths. In particular, as shown in top view 901, an inner set of gas path holes 912 substantially form a ring of holes a particular radial distance from a center of the lid 902. The inner set of gas path holes 912 can direct etch gasses from a gas hub and through the body of the gas delivery nozzle 906. For example, the inner set of gas path holes 912 can be positioned to direct charged particles formed from the etch gases in the process chamber to a particular central region of a target substrate.

An outer set of gas path holes 914 substantially form a ring of holes a particular radial distance from the center of the lid 902 that is greater than the radial distance of the inner set of gas path holes 912. The outer set of gas path holes 914 can direct etch gasses from the gas hub and through the body of the gas delivery nozzle 906. For example, the outer set of gas path holes 914 can be positioned to direct charged particles formed from the etch gases in the process chamber to a particular edge region of a target substrate.

The number and arrangement of gas paths represented by the set of inner gas path holes and the set of outer gas path holes can vary as described above with respect to FIG. 3B.

The top view 901 also illustrates four mounting holes 916. The mounting holes 916 can be similar to the mounting holes described above with respect to FIG. 2 and used to secure components of an inductively coupled plasma source and the gas hub to the lid 902.

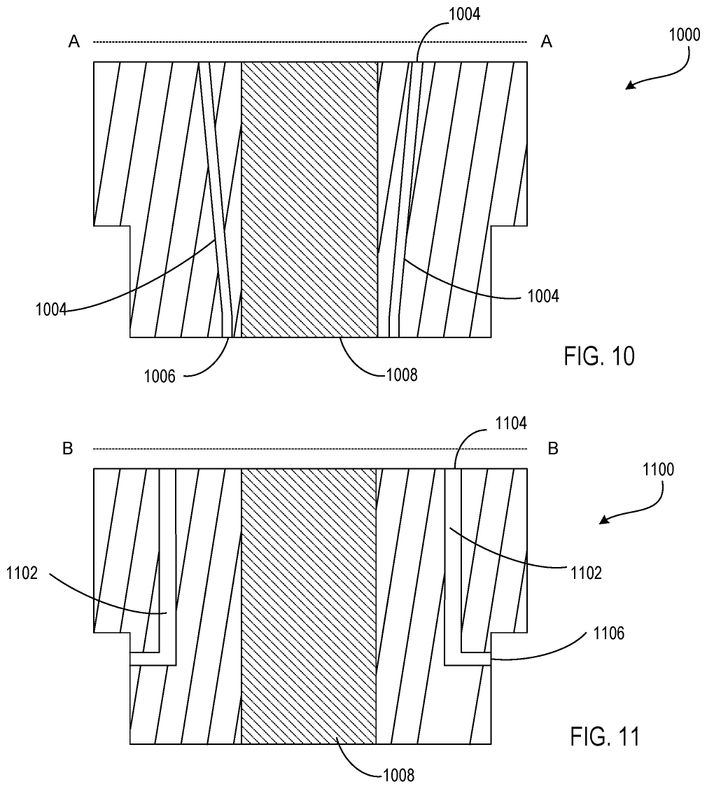

FIG. 10 shows a first schematic cross-sectional view 1000 of the gas delivery nozzle 906 illustrating first gas paths 1002 through the lid 902 of FIG. 9A. In particular, cross-sectional view 1000 corresponds to a cross section along the path A-A shown in FIG. 9B.

As shown in FIG. 10, the lid 902 includes a pair of gas paths 1002. Specifically, these gas paths correspond to a pair of the inner set of gas path holes 912 shown in in FIG. 9B. Thus, there are multiple additional gas paths on different cross sections of the lid 902. In particular, etch gasses from the hub (e.g., hub 206 of FIG. 2) enter each respective gas path 1002 at a corresponding input 1004 and exit the gas delivery nozzle toward the process chamber through an output 1006. Each gas path 1002 can be, for example, a cylindrically formed hole through the lid 902. In the example shown in FIG. 4, the gas paths 1002 are angled such that the input 1004 has a greater radius from a center point of the lid 902 than the output 1006. Each gas path 1002 corresponding to an inner set of gas paths can have outputs configured to direct charged particles formed from the etch gasses toward a central region of a substrate positioned in the process chamber.

A central portion 1008 corresponds to an aperture formed through the center of the lid 902 and can be configured, or omitted, similarly to the aperture 408 described above with respect to FIG. 4.

FIG. 11 shows a second schematic cross-sectional view 1100 of the gas delivery nozzle 906 illustrating second gas paths 1102 through the lid of FIG. 9A. In particular, cross-sectional view 1100 corresponds to a cross section along the path B-B shown in FIG. 9B.

As shown in FIG. 11, the lid 902 includes a pair of gas paths 1102. Specifically, these gas paths correspond to a pair of the outer set of gas path holes 914 shown in in FIG. 9B. Thus, there are multiple additional gas paths on different cross sections of the lid 902. In particular, etch gasses from the hub (e.g., hub 206 of FIG. 2) enter each respective gas path 1102 at a corresponding input 1104 and exit the gas delivery nozzle toward the process chamber through an output 1106. Each gas path 1102 can be, for example, can be formed by creating holes into the lid 902 to form a cylindrical gas pathway. In the example shown in FIG. 11, the gas paths 102 include a substantially 90 degree bend such that the output 1106 is on a sidewall of the gas delivery nozzle 906.

As described above with respect to FIG. 9, the gas delivery nozzle portion of the lid 902 protrudes from the surface of the lid 902 in a substantially cylindrical shape. The protrusion allows the output of particular gas paths to be located along the side of the protrusion as in output 1106 or the bottom of the protrusion as in output 1006 shown in FIG. 10. The location of the output along the sidewall of the protruding gas delivery nozzle portion can vary depending on the design and application. Each gas path 1102 corresponding to an outer set of gas paths can have outputs configured to direct charged particles formed from the etch gasses toward an edge region of a substrate positioned in the process chamber. In particular, when the lid 902 is closed on the chamber, the gas delivery nozzle 906 protrudes into the process chamber.

Different etch gas mixtures and etch gas pressures can be passed through the gas paths 1002 and gas paths 1102, which can be independently controlled, as described above with respect to FIGS. 4-5.

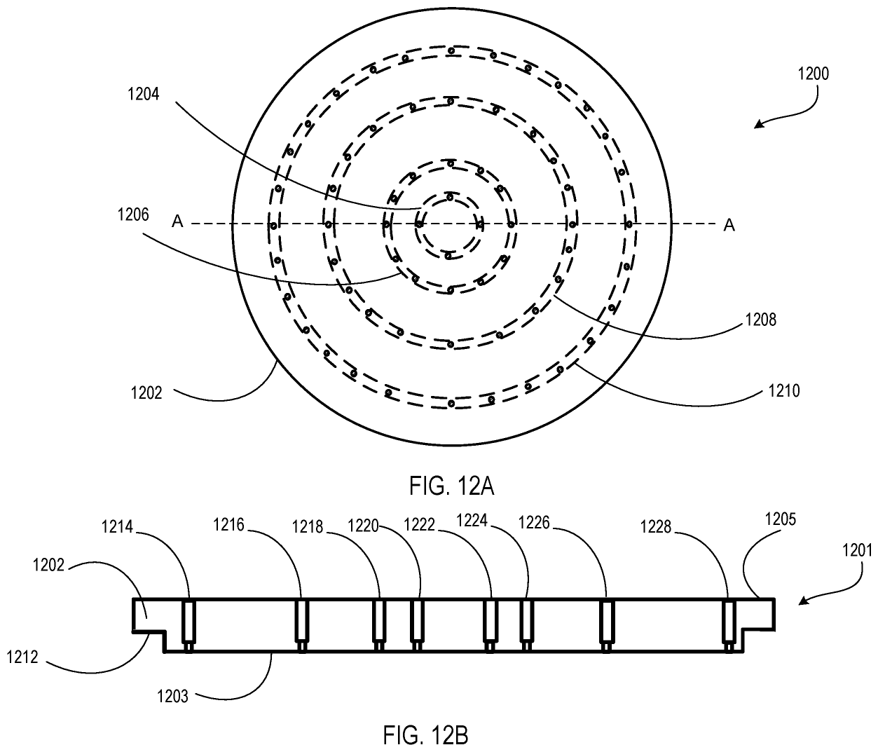

FIG. 12A shows a top view 1200 of an example lid 1202 of a plasma processing chamber. FIG. 12B shows a schematic cross-sectional view 1201 of the lid 1202 of FIG. 12A.

Similar to the lid examples described above, lid 1202 is formed from a single piece of dielectric material, e.g., a ceramic material such as Alumina or Yttria, quartz, or other suitable dielectric material. The lid 1202 can be substantially disk shaped. As illustrated by top view 1200, the lid 1202 can have a substantially circular top surface 1205 having a particular diameter. In this specification, a “top” of the lid 1202 refers to a side of the lid 1202 facing the gas hub. The shape and diameter of the lid 1202 can be configured according to the particular plasma processing chamber design. In particular, in this example, nearly the entire lid 1202 is used to provide the gas delivery nozzle rather than just a smaller central region of the lid as described above.

The lid 1202 has a specified thickness that can be determined based on various design parameters including material, strength needed, and overall system design. The lid 1202 can include a lip portion 1212 for seating the lid on one or more sidewall edges on the opening of the plasma processing chamber.

As shown in FIG. 12A, four rings of gas path holes are illustrated including a first ring 1204, second ring 1206, third ring 1208, and fourth ring 1210. Each of these rings define a region having multiple gas path holes that provide an inlet for etch gases. The number of gas paths in each ring can vary depending on the particular application and design of the plasma processing chamber.

While the rings are illustrated, each ring need only illustrate the location of the gas inlet holes and do not necessarily correspond to any ring shaped structure on the surface of the lid 1202. Each ring can correspond to a particular zone. Each zone can indicate a particular region of a substrate in which the plasma formed from etch gasses emitted from the bottom surface 1203 of the lid 1202 is directed. Thus, in contrast to the “inner” and “edge” regions described above, the lid 1202 can direct charged particles to four concentric regions of the substrate corresponding to each respective ring zone.

Cross-sectional view 1201 illustrates a cross section along line A-A of FIG. 12A passing through a set of gas paths including gas paths 1214, 1216, 1218, 1220, 1222, 1224, 1226, and 1228. Gas paths 1220 and 1222 correspond to gas paths of the first ring 1204. Gas paths 1218 and 1224 correspond to gas paths of the second ring 1206. Gas paths 1216 and 1226 correspond to gas paths of the third ring 1208. Gas paths 1214 and 1228 correspond to gas paths of the fourth ring 1210.

In particular, etch gasses enter each respective gas path at a corresponding input on the top surface 1205 of the lid 1202 and exit the lid 1202 to enter the process chamber through a corresponding output on the bottom surface 1203 of the lid 1202. Each gas path can be, for example, a cylindrically formed hole through the lid 1202. In the example shown in FIG. 12B, the gas paths narrow near each output. In other implementations, the diameter of the gas path is constant. In some implementations, the gas pressure of etch gasses provided to each ring of gas paths is independently controlled. This can allow for control or adjustment of an etching rate at each region of the substrate corresponding to a particular ring.

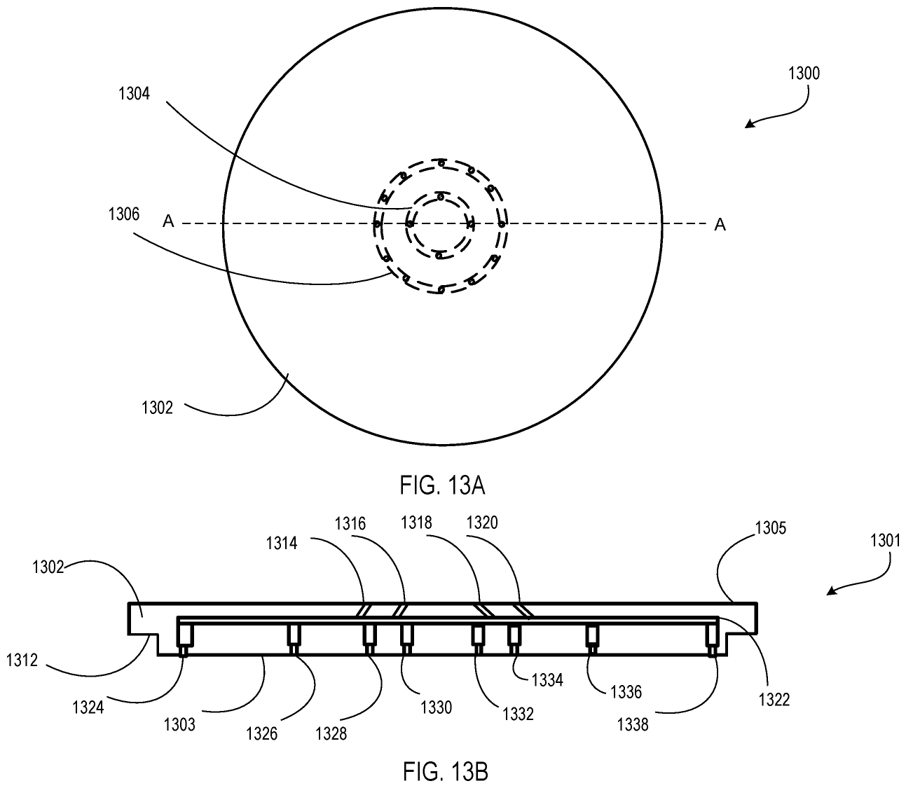

FIG. 13A shows a top view 1300 of an example lid 1302 of a plasma processing chamber. FIG. 13B shows a schematic cross-sectional view 1301 of the lid 1302 of FIG. 13A.

Similar to the lid examples described above, lid 1302 is formed from a single piece of dielectric material, e.g., a ceramic material such as Alumina or Yttria, quartz, or other suitable dielectric material. The lid 1302 can be substantially disk shaped. As illustrated by top view 1300, the lid 1302 can have a substantially circular top surface 1305 having a particular diameter. In this specification, a “top” of the lid 1302 refers to a side of the lid 1302 facing the gas hub. The shape and diameter of the lid 1302 can be configured according to the particular plasma processing chamber design.

The lid 1302 has a specified thickness that can be determined based on various design parameters including material, strength needed, and overall system design. The lid 1302 can include a lip portion 1312 for seating the lid on one or more sidewall edges on the opening of the plasma processing chamber.

As shown in FIG. 13A, two rings of gas path holes are illustrated including a first ring 1304 and a second ring 1306. Each of these rings define a region having multiple gas path holes that provide an inlet for etch gases. The number of gas paths in each ring can vary depending on the particular application and design of the plasma processing chamber.

While the rings are illustrated, each ring need only illustrate the location of the gas inlet holes and do not necessarily correspond to any ring shaped structure on the surface of the lid 1302.

Cross-sectional view 1301 illustrates a cross section along line A-A of FIG. 13A passing through a set of input gas paths from the top surface 1305 of the lid 1302 including input gas paths 1314, 1316, 1318, and 1320. These input gas paths lead to a plenum 1322 formed within the body of the lid 1302.

The plenum 1322 defines a space within the lid 1302 into which etch gases from each of the input gas paths flow. Etch gases in the plenum 1322 then flow out of the plenum 1322 to a particular output gas path. In FIG. 13B, there are eight output gas paths shown including 1324, 1326, 1328, 1330, 1332, 1334, 1336 and 1338.

These output gas paths can correspond to different zones along the inner surface 1303 of the lid 1302. For example, the inner surface 1303 of the lid 1302 can include rings of output gas holes similar to those shown on the top surface 1205 of lid 1202 shown in FIG. 12A. Thus, using a smaller number of input gas paths that are closer to a center point of the lid 1302, etch gases can be provided to a number of regions of the substrate. For example, output gas paths 1330 and 1332 can correspond to a first zone of output paths that provides etching to substantially a first region of the substrate. Thus, similar to FIGS. 12A-B, the output gas paths of FIG. 13B can provide etch gases to multiple regions of the substrate.

In FIG. 13, only a single plenum 1322 is shown. However, in some implementations there could be multiple plenums fed by one or more input gas paths. For example, the input gas paths 1316 and 1318 could feed etch gases to a first plenum and the input gas paths 1314 and 1320 could feed etch gases to a second plenum. Each of the first and second plenums could then be coupled to different sets of output gas paths. Having multiple plenums can allow for different gas pressure to be introduced to different plenums, which in turn can allow for controlling etching at two different regions of the substrate. In other implementations, more than two plenums can be used to control etching of corresponding substrate regions.

The integrated lid can be fabricated using one or more manufacturing techniques, for example, using wet casting, subtractive manufacturing, additive manufacturing, sintering, or other techniques. The gas paths can be formed, for example, by drilling or other machining techniques. In some implementations, additive manufacturing techniques can be used to fabricate the integrated lid in which the shape and gas flow paths are formed layer by layer in an additive manner, e.g., using three dimensional printing.

In one embodiment, three dimensional printing (or 3-D printing) may be used to produce (or make) the integrated lid described herein. In one embodiment, a computer (CAD) model of the required part is first made and then a slicing algorithm maps the information for every layer. A layer starts off with a thin distribution of powder spread over the surface of a powder bed. A chosen binder material then selectively joins particles where the object is to be formed. Then a piston which supports the powder bed and the part-in-progress is lowered in order for the next powder layer to be formed. After each layer, the same process is repeated followed by a final heat treatment to make the object. Since 3-D printing can exercise local control over the material composition, microstructure, and surface texture, various (and previously inaccessible) geometries may be achieved with this method.

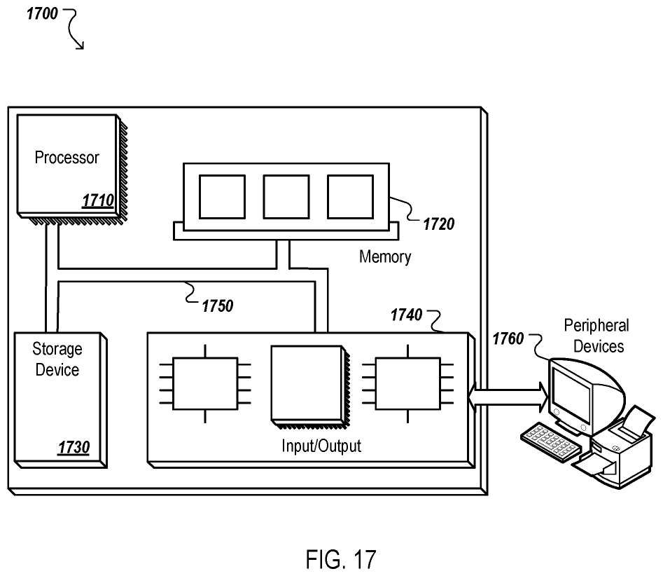

In one embodiment, an integrated lid and gas delivery nozzle as described herein may be represented in a data structure readable by a computer rendering device or a computer display device. FIG. 17 is a schematic representation of a computer system with a computer-readable medium according to one embodiment. The computer-readable medium may contain a data structure that represents an integrated lid. The data structure may be a computer file, and may contain information about the structures, materials, textures, physical properties, or other characteristics of one or more articles. The data structure may also contain code, such as computer executable code or device control code that engages selected functionality of a computer rendering device or a computer display device. The data structure may be stored on the computer-readable medium. The computer readable medium may include a physical storage medium such as a magnetic memory, floppy disk, or any convenient physical storage medium. The physical storage medium may be readable by the computer system to render the article represented by the data structure on a computer screen or a physical rendering device which may be an additive manufacturing device, such as a 3D printer.

As noted above the lid and chamber walls may be coated in a material to help protect the lid or chamber walls from the etch plasma. For example, a chamber lid can be formed from Alumina, which can be made more resistant to etch plasma by adding a coating. Typically, a ceramic material coating is applied, for example, based on a material having a greater etch plasma resistance, such as a Yttrium-based material e.g., Yttrium Oxide. Some techniques for applying a ceramic coating include thermal spray coating, or specifically plasma spray coatings.

Additionally, the coating can be formed through an application of one or more layers of ceramic nanoparticles that can be mixed with a polymer binder to provide sufficient coating structure and adhesion while resisting plasma etch. As use herein, a nanomaterial is a material with some physical feature, e.g., particle dimension, porosity, crystal size, etc., that is less than 100 nanometers in length.

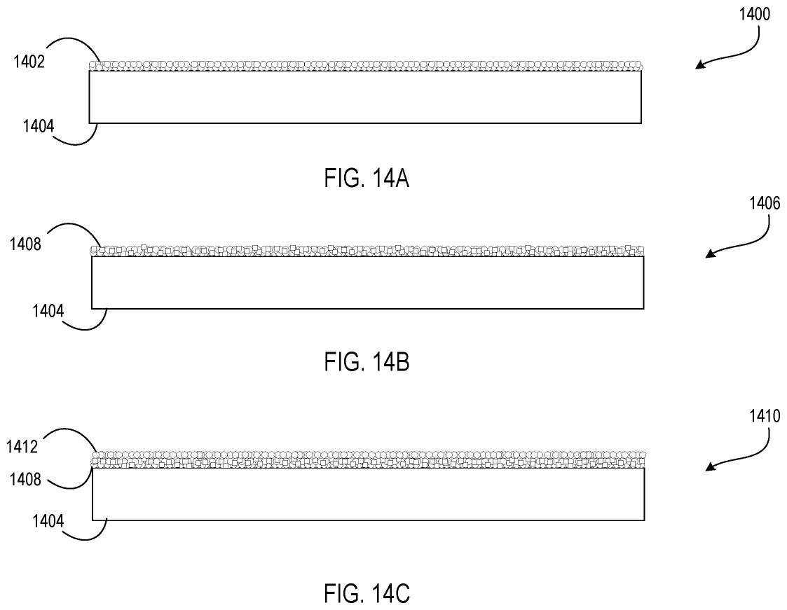

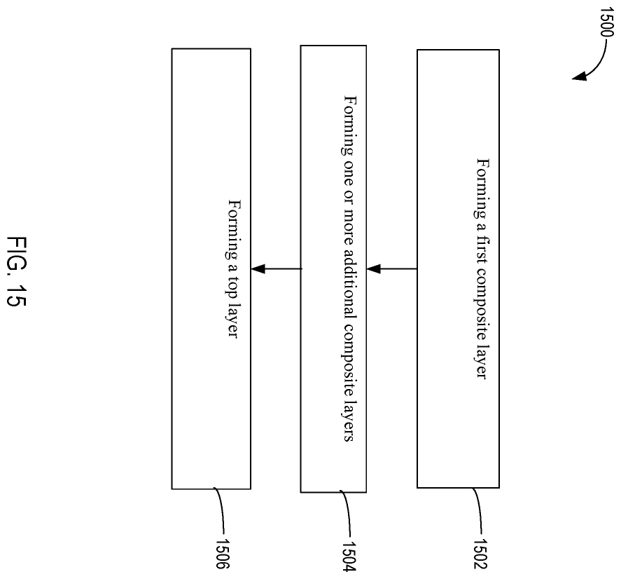

FIGS. 14A-C show cross sectional views of an example of building layers on a base material. FIG. 14A shows a cross-sectional view 1400 of an initial layer on a structure 1404. In particular, a layer 1402 of nanomaterial is spread on a surface of the structure 1404, e.g., a portion of a chamber wall or lid for a plasma-based processing system. The nanocomposite can be a composed of a particular etch resistant ceramic including, for example, Yttrium based ceramics including YO, YOF, or YF, alumina-based ceramics including Al₂O₃, both, including YAG (Y₃Al₅O₁₂) and other suitable ceramics. In some implementations, a nanomaterial powder is deposited on a thus surface using a solution or slurry precursor plasma spray.

In some implementations, a free side of a double-sided adhesive tape is first placed on the surface of the structure 1404 with the backing of the adhesive tape removed. Nanoparticles are positioned on top of and within the adhesive.

FIG. 14B shows a cross sectional view 1406 of a composite layer 1408 on the surface of the structure 1404. The composite layer 1408 includes the nanomaterial layer 1402 combined with a polymer. For example, a particular amount of a liquid polymer can be added to the nanomaterial layer 1402 so that the liquid polymer mixes with the nanoparticles. The polymer binder can be applied to the nanomaterial layer using various suitable techniques including spraying and brushing. For example, a fine mist spray can be used to evenly distribute small amounts of polymer binder across the surface.

In some implementations, the ratio of nanoparticles to polymer is high so that a large amount of the material in the composite layer is ceramic nanoparticles, e.g., where polymer makes up from 10 to 50 percent of the total volume. Various suitable liquid polymers can be selected. Suitability can be based on viscosity, curing method, and heat resistance. For example, when used for a coating in a plasma based processing chamber, the processing chamber is heated, e.g., to 50 degrees or 90 degrees Celsius. The polymer can be selected to so that it does not melt or deform at those operating temperatures. Curing can be based on, for example, time, applied heat, or UV light.

In some implementations, the composite layer 1408 is premixed and then applied to the structure 1404. For example, the polymer and nanoparticles portions can be premixed and then deposited on the surface of the structure, for example, by extruding the combined material, spreading the material, etc. A particular polymer can cure based on time, e.g., in response to exposure to air, which provides a maximum time to form the layer on the substrate. Other polymers require heat or light to cure and can be mixed and deposited into an even layer before curing.

Multiple composite layers can be formed on top of composite layer 1408 until a specified thickness is achieved. For example, a layer can be formed as described above. The polymer can be cured before adding a second layer on top of the previously layer in a similar manner to forming composite layer 1408.

In some implementations, different formulations of each layer can be generated. For example, the ratio of nanoparticles to polymer can change as well as the type of polymer. Moreover, in some implementations, the nanoparticles composition can also change. For example, one nanoparticles composition may be used for one or more layers followed by a top layer composition that has a stronger etch plasma resistance. Additionally, some nanoparticles compositions may have different structural strength characteristics. Thus, for example, one or more base layers may be formed from nanoparticles composition having higher structural strength while one or more top layers may be formed from nanoparticles composition having greater plasma resistance. Furthermore, the ratios of nanoparticles to polymer binder may also vary between layers to provide particular strength and/or plasma characteristics.

FIG. 14C shows a cross sectional view 1410 of a top layer 1412. The top layer 1412 represents a final layer after one or more previous composite layers 1408. In some implementations, the top layer 1412 is formed by adding a nanoparticle layer before the immediately preceding layer has cured. Thus, nanoparticle of the top layer 1412 can adhere to the polymer of the preceding layer before curing is completed. The resulting top layer 1412 is predominantly if not entirely formed of the nanoparticles. This top layer can be, for example, substantially a monolayer of one particle diameter thickness. This prevents surface exposure of polymer, which is more susceptible to the etch plasma in the processing chamber, resulting in a more durable coating.

In some implementations, composite layers are each formed by premixing a specified amount of nanoparticles and liquid polymer binder. The mixture can then be extruded onto a surface. Based on the amount of liquid polymer used to sufficiently wet the nanoparticles, the composite material extruded should be thick and not runny. Upon curing, a completed composite layer can have a next layer added in a similar manner until a desired coating thickness is achieved.

In some implementations, solid polymer pellets can be used. The ceramic and polymer can be milled together so that each nanostructured particle is a composite particle of ceramic and polymer. The composite powder could then be laid down upon a surface being coated and then cured (e.g., with heat) for form a completed composite layer. Additional layers can then be formed on top of each preceding layer in a similar manner. The same composite powder may be cold sprayed onto surfaces. Cold spraying can allow for the application of the coating on surfaces having an orientation that is not parallel to ground so that gravity cannot be relied upon to keep the layer in place, e.g., for coating vertical surfaces.

In some implementations, the top layer is simply a final composite layer of nanoparticles and polymer. The coated component can be exposed to an environment, such as a plasma chamber, that erodes away a portion of the final layer, predominantly the polymer, so that the remaining portion of the top layer has a surface that is mostly if not entirely nanoparticles.

FIG. 15 is a flow diagram of an example method 1500 of forming a nanostructured ceramic-matrix coating. For convenience, the method 1500 will be described with respect to a system that performs the method 1500, for example, a system for coating components of a plasma-based processing system.

The system forms a first composite layer (1502). The system can form the first composite layer according to various techniques as described above. For example, a layer of nanoparticles can be spread over a surface being coated. A precise amount of liquid polymer can then be applied to the powder, e.g., in an even distribution. Alternatively, the nanoparticles and liquid polymer can be premixed and extruded onto the surface being coated.

The system sequentially forms one or more additional composite layers (1504). The number of layers can vary depending on the application. Each additional composite layer can be formed on a cured composite layer to build thickness of the coating layer by layer.

The system forms a top layer and completes the coating (1506). Forming a top layer can include laying a final composite layer or laying a layer of nanoparticles only, e.g., on top of a composite layer where the mixed in polymer has not yet cured. When forming a top layer as a composite layer, in some cases the top layer is then eroded to remove exposed polymer.

A coating formed from nanomaterials can be robust. The coating can have fewer flaws than other techniques of generating a coating and can have a higher etch plasma resistance. However, some erosion in the plasma environment may still occur. The erosion will likely be of individual nanoparticles having small mass and momentum. For plasma-based substrate processing systems, the nanoparticles that erode are unlikely to settle on the substrate/wafer. This is because in a vacuum environment, nanoparticles given their small mass are likely to be exhausted from the chamber by the vacuum system.

In addition to creating coatings including a coating on an integrated lid, as described in FIGS. 1-13, or other chamber walls, the above techniques can also be applied to repairing components. For example, a component with an existing coating can have a portion of the coating that needs repair due to erosion or accidental damage. For example, a lid of a plasma-processing chamber can have a damaged coating. In some instances, different regions may wear differently due to plasma exposure rather than all erode at a same rate. In some other instances, the entire coating has been reduced by a specified amount so that repair is needed. For example, there can be a minimum thickness for the coating and when the coating erodes below this minimum threshold, repair is needed. Whether a portion or the entire surface, the above techniques can be used to add new composite layers of ceramic nanoparticles and polymer to restore the surface to a desired coating thickness.

In addition to creating and repairing, the above techniques can also be applied to additively manufacturing individual components. That is, a system can use a combination of nanoparticles and polymer to fabricate various individual components.

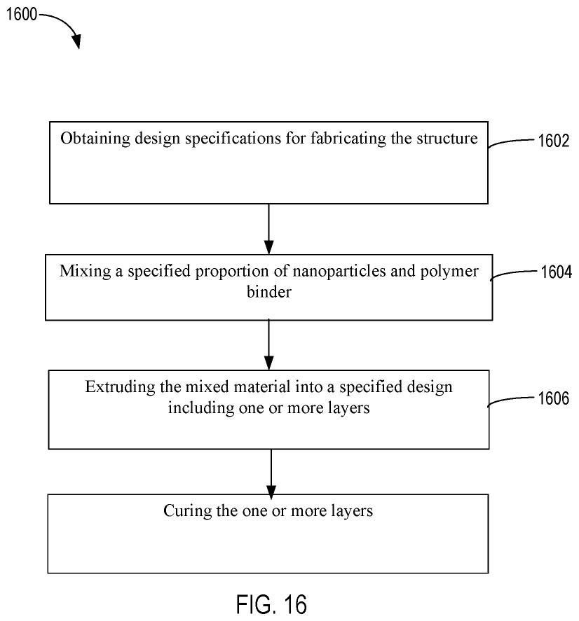

FIG. 16 is a flow diagram of an example method 1600 of additively manufacturing a structure from nanoparticles. For convenience, FIG. 16 is described with respect to a system that performs the method 1600, e.g., an additive manufacturing system.

The system obtains design specifications for fabricating the structure (1602). For example, a prototype or sample structure can be scanned or sliced into layers so that the structure at each layer is captured. This can be represented in a data structure or file that can be read by the system and used to control deposition of one or more layers of material.

The system mixes a specified proportion of nanoparticles and polymer (1604). In some implementations, the specified proportion is a majority of nanoparticles to polymer. The particular nanoparticles and polymer can be selected based on the requirements for the component including, for example, strength and heat resistance. Additionally, the polymer can be selected base in part on curing type and duration. For example, UV cured polymers may need to be extruded in thin layers while a heat cured polymer may be able to be built up in thicker layers up to and including the entire component. The curing time needs to allow for the mixing and extrusion of the mixed material.

The system extrudes the mixed material into a specified design (1606). The mixed material can be extruded in layers similar to that of 3D printing where layers of the mixture are extruded according to a design pattern. Each layer can be cured and then a next layer formed on top of the previous layer with more mixed material. In some other implementations, thick layers can be extruded for a particular type of component that does not have intricate interior components or sagging concerns.

The system cures the resulting component (1608). The curing process depends on the polymer used and the extrusion technique. The system can cure individual layers as each is extruded, e.g., using UV light or heat treatment. In some implementations, a thicker piece that may encompass an entire component can be cured in a single step using one of the curing techniques. For example, the component can be slowly rotated while applying heat to evenly cure the polymer material.

FIG. 17 is a block diagram of an example computer system 1700 that can be used to perform operations described above. For example, such as operations performed by the electrostatic chuck model. The system 1700 includes a processor 1710, a memory 1720, a storage device 1730, and an input/output device 1740. Each of the components 1710, 1720, 1730, and 1740 can be interconnected, for example, using a system bus 1750. The processor 1710 is capable of processing instructions for execution within the system 1700. In one implementation, the processor 1710 is a single-threaded processor. In another implementation, the processor 1710 is a multi-threaded processor. The processor 1710 is capable of processing instructions stored in the memory 1720 or on the storage device 1730.

The memory 1720 stores information within the system 1700. In one implementation, the memory 1720 is a computer-readable medium. In one implementation, the memory 1720 is a volatile memory unit. In another implementation, the memory 1720 is a non-volatile memory unit.

The storage device 1730 is capable of providing mass storage for the system 1700. In one implementation, the storage device 1730 is a computer-readable medium. In various different implementations, the storage device 1730 can include, for example, a hard disk device, an optical disk device, a storage device that is shared over a network by multiple computing devices (e.g., a cloud storage device), or some other large capacity storage device.

The input/output device 1740 provides input/output operations for the system 1700. In one implementation, the input/output device 1740 can include one or more of a network interface device, e.g., an Ethernet card, a serial communication device, e.g., and RS-232 port, and/or a wireless interface device, e.g., and 802.11 card. In another implementation, the input/output device can include driver devices configured to receive input data and send output data to peripheral devices 1760, e.g., keyboard, printer and display devices. Other implementations, however, can also be used, such as mobile computing devices, mobile communication devices, set-top box television client devices, etc.

Although an example processing system has been described in FIG. 17, implementations of the subject matter and the functional operations described in this specification can be implemented in other types of digital electronic circuitry, or in computer software, firmware, or hardware, including the structures disclosed in this specification and their structural equivalents, or in combinations of one or more of them.

Aspects of the subject matter and the actions and operations described in this specification, for example, computing devices such as controller 165 and processes performed by controller 165 such as controlling of the gas panel and distribution of process gases to a plasma processing chamber, can be implemented in digital electronic circuitry, in tangibly-embodied computer software or firmware, in computer hardware, including the structures disclosed in this specification and their structural equivalents, or in combinations of one or more of them.

The subject matter and the actions and operations described in this specification can be implemented as or in one or more computer programs, e.g., one or more modules of computer program instructions, encoded on a computer program carrier, for execution by, or to control the operation of, data processing apparatus. The carrier can be a tangible non-transitory computer storage medium. Alternatively, or in addition, the carrier can be an artificially-generated propagated signal, e.g., a machine-generated electrical, optical, or electromagnetic signal, which is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

The term “data processing apparatus” encompasses all kinds of apparatus, devices, and machines for processing data, including by way of example a programmable processor, a computer, or multiple processors or computers. Data processing apparatus can include special-purpose logic circuitry, e.g., an FPGA (field programmable gate array), an ASIC (application-specific integrated circuit), or a GPU (graphics processing unit). The apparatus can also include, in addition to hardware, code that creates an execution environment for computer programs, e.g., code that constitutes processor firmware, a protocol stack, a database management system, an operating system, or a combination of one or more of them.

A computer program can be written in any form of programming language, including compiled or interpreted languages, or declarative or procedural languages; and it can be deployed in any form, including as a stand-alone program, e.g., as an app, or as a module, component, engine, subroutine, or other unit suitable for executing in a computing environment, which environment can include one or more computers interconnected by a data communication network in one or more locations.

A computer program can, but need not, correspond to a file in a file system. A computer program can be stored in a portion of a file that holds other programs or data, e.g., one or more scripts stored in a markup language document, in a single file dedicated to the program in question, or in multiple coordinated files, e.g., files that store one or more modules, sub-programs, or portions of code.

The processes and logic flows described in this specification can be performed by one or more computers executing one or more computer programs to perform operations by operating on input data and generating output. The processes and logic flows can also be performed by special-purpose logic circuitry, e.g., an FPGA, an ASIC, or a GPU, or by a combination of special-purpose logic circuitry and one or more programmed computers.

Computers suitable for the execution of a computer program can be based on general or special-purpose microprocessors or both, and any other kind of central processing unit. Generally, a central processing unit will receive instructions and data from a read-only memory or a random-access memory or both. The essential elements of a computer are a central processing unit for executing instructions and one or more memory devices for storing instructions and data. The central processing unit and the memory can be supplemented by, or incorporated in, special-purpose logic circuitry.

Generally, a computer will also include, or be operatively coupled to, one or more mass storage devices, and be configured to receive data from or transfer data to the mass storage devices. The mass storage devices can be, for example, magnetic, magneto-optical, or optical disks, or solid-state drives. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device, e.g., a universal serial bus (USB) flash drive, to name just a few.

While this specification contains many specific implementation details, these should not be construed as limitations on the scope of what is being claimed, which is defined by the claims themselves, but rather as descriptions of features that can be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features can be described above as acting in certain combinations and even initially be claimed as such, one or more features from a claimed combination can in some cases be excised from the combination, and the claim can be directed to a subcombination or variation of a subcombination.

Similarly, while operations are depicted in the drawings and recited in the claims in a particular order, this by itself should not be understood as requiring that such operations be performed in the particular order shown or in sequential order, or that all illustrated operations be performed, to achieve desirable results. In certain circumstances, multitasking and parallel processing can be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing can be advantageous.

What is claimed is:

1. A system for semiconductor processing, the system comprising:
a chamber body comprising a plurality of walls for enclosing a processing region;
a first substrate support within the chamber body and configured to retain a substrate in the processing region of the chamber;
a plasma source configured to direct RF energy into the chamber body; and
a chamber lid configured to enclose the first processing region when in a closed position relative to the chamber body, the chamber lid integrating a lid portion and a gas delivery nozzle portion into a single structure, the chamber lid being formed from a dielectric material configured to allow RF energy generated by the plasma source to pass through the lid, the chamber lid further comprising a plurality of gas flow paths that each traverse a region of the chamber lid from an input location at a first surface of the chamber lid to a respective output location on a different surface of the chamber lid through which etch gases are distributed to particular portions of the processing region.

2. The system of claim 1, wherein the region of the chamber lid comprises a cylindrical protrusion extending from a surface of the chamber lid.

3. The system of claim 2, wherein one or more output locations located on a sidewall surface of the cylindrical protrusion.

4. The system of claim 1, wherein the plurality of gas flow paths comprise an inner group of gas paths and an outer group of gas paths, the inner group of gas paths being configured to distribute etch gases for etching a central region of the substrate, the outer group of gas paths being configured to distribute etch gases for etching an edge region of the substrate.

5. The system of claim 4, wherein each gas path of the outer group of gas paths is angled such that the output location of the gas path has a radius to a center point of an inner surface of lid facing the processing region that is greater than a radius of the input location of the gas path to a center point of a top surface of the lid facing the plasma source.

6. The system of claim 4, wherein each gas path of the inner group of gas paths is angled such that the output location of the gas path has a radius to a center point of an inner surface of lid facing the processing region that is less than a radius of the input location of the gas path to a center point of a top surface of the lid facing the plasma source.

7. The system of claim 1, wherein the dielectric material of the lid comprises one of a ceramic material or a quartz material.

8. The system of claim 1, wherein the chamber lid comprises a plurality of concentric rings of gas flow paths, wherein each ring of gas flow paths corresponds to a plurality of input gas flow paths belonging to a particular zone and wherein each zone is configured to provide a particular gas pressure of etch gases to a particular area of the processing region.

9. The system of claim 1, wherein the chamber lid comprises a first plurality of input gas paths coupled to a plenum formed in a body of the chamber lid and a second plurality of output gas paths coupled to the plenum, wherein a number of output gas paths is greater than a number of input gas paths.

10. The system of claim 1, wherein the chamber lid further comprises a plurality of mounting holes, each mounting hole comprising a threaded hole formed in the chamber lid, a threaded plastic insert positioned within the threaded hole, and a metallic helical coil embedded into the plastic insert and configured to receive an attaching structure.

11. A chamber lid of a semiconductor processing chamber comprising:
a dielectric material having a substantially disk shape and integrating a lid portion and a gas delivery nozzle portion into a single structure, the chamber lid comprising a plurality of gas flow paths that each traverse a region of the chamber lid from an input location at a first surface of the chamber lid to a respective output location on a different surface of the chamber lid and through which etch gases are distributed to particular portions of a processing region of the processing chamber.

12. The chamber lid of claim 11, wherein the dielectric material allows RF energy generated by the plasma source to pass through the chamber lid and into the processing chamber.

13. The chamber lid of claim 11, wherein the region of the chamber lid comprises a cylindrical protrusion extending from a surface of the chamber lid.

14. The chamber lid of claim 13, wherein one or more output locations located on a sidewall surface of the cylindrical protrusion.

15. The chamber lid of claim 11, wherein the plurality of gas flow paths comprise an inner group of gas paths and an outer group of gas paths, the inner group of gas paths being configured to distribute etch gases for etching a central region of a substrate positioned within the processing chamber, the outer group of gas paths being configured to distribute etch gases for etching an edge region of the substrate.

16. The chamber lid of claim 15, wherein each gas path of the outer group of gas paths is angled such that the output location of the gas path has a radius to a center point of an inner surface of lid facing the processing chamber that is greater than a radius of the input location of the gas path to a center point of a top surface of the lid facing a plasma source.

17. The system of claim 11, wherein the dielectric material of the lid comprises one or a ceramic material or a quartz material.

18. The system of claim 11, wherein the chamber lid comprises a plurality of concentric rings of gas flow paths, wherein each ring of gas flow paths corresponds to a plurality of input gas flow paths belonging to a particular zone and wherein each zone is configured to provide a particular gas pressure of etch gases to a particular area of the processing region.

19. The system of claim 11, wherein the chamber lid further comprises a plurality of mounting holes, each mounting hole comprising a threaded hole formed in the chamber lid, a threaded plastic insert positioned within the threaded hole, and a metallic helical coil embedded into the plastic insert and configured to receive an attaching structure.

20. A structure embodied in a machine readable medium used in a design process, the structure comprising:
a chamber lid comprising a dielectric material having a substantially disk shape and integrating a lid portion and a gas delivery nozzle portion into a single structure, the chamber lid comprising a plurality of gas flow paths that each traverse a central region of the chamber lid from an input location at a first surface of the chamber lid to a respective output location on a different surface of the chamber lid.

21. A method of forming a coating on a structure comprising:
forming a first composite layer, the first composite layer comprising a ceramic nanoparticles and a polymer binder, wherein the polymer is cured to form the first layer;
forming one or more second composite layers in sequential order on top of the first composite layer, each second composite layer comprising the ceramic nanoparticles and polymer that is cured after being formed on a preceding composite layer; and
forming a top layer, wherein the top layer has a surface substantially made of the ceramic nanoparticles.

22. The method of claim 21, wherein forming the first composite layer comprises depositing a nanoparticles on the structure and then applying a specified amount of polymer to the powder.

23. The method of claim 21, wherein forming the first composite layer comprises premixing the nanoparticles and polymer before applying to the structure.

24. The method of claim 21, wherein forming the top layer comprises depositing a layer of the nanoparticles on top of a final second composite layer before curing the polymer of the final second composite layer.

25. The method of claim 21, wherein forming the top layer comprises forming a layer of the nanoparticles and polymer and then eroding the top layer to remove exposed polymer.

26. A method comprising:
obtaining design parameters for a structure;
mixing a specified proportion of a ceramic nanoparticles and a polymer;
forming one or more composite layers of the ceramic nanoparticles and polymer according to the design parameters; and
curing the resulting structure.
